(19) United States
(12) Patent Application Publication
(10) Pub. No.: US 2023/0044831 A1
(43) Pub. Date: Feb. 9, 2023

(54) Sputtering Target

(71) Applicant: FHR Anlagenbau GmbH, Ottendorf-Okrilla (DE)

(72) Inventors: Ronny Kleinhempel, Lunzenau (DE); Beate Bergk, Dresden (DE)

(73) Assignee: FHR Anlagenbau GmbH, Ottendorf-Okrilla (DE)

(21) Appl. No.: 17/816,781

(22) Filed: Aug. 2, 2022

(30) Foreign Application Priority Data
Aug. 4, 2021 (DE) 10 2021 120 332.5

(51) Int. Cl. C23C 14/35; H01J 37/34

(52) U.S. Cl. CPC C23C 14/352; H01J 37/3405; H01J 37/3426

(57) ABSTRACT

A multiple sputtering target for magnetron arrangements has a tubular magnetron, for coating substrates in a vacuum chamber. The tubular magnetron is mounted in an end block or some other drive unit. A magnet bar is located in the tubular magnetron. Substrates transported along a circular path through a vacuum chamber can be coated with a selectable multiplicity of materials by magnetron sputtering. At least one polygonal carrier tube having an angular cross section has a plurality of longitudinally extending outer surfaces for receiving targets. A free extends longitudinally through the polygonal carrier tube. A magnet bar for forming plasma clouds outside the polygonal carrier tube is located in a working position in front of a target which can be selected by rotating the polygonal carrier tube. The moving or stationary substrate is located at a predetermined distance in front of the plasma clouds.

### CROSS-REFERENCE TO RELATED APPLICATION

This application claims the benefit of German Patent Application No. 10 2021 120 332, filed 4 Aug. 2021, the contents of which is hereby incorporated by reference in its entirety.

### TECHNICAL FIELD

The disclosure relates to a multiple sputtering target for magnetron arrangements having tubular magnetrons, for coating stationary substrates or substrates which are transported along or on a circular path through a vacuum chamber.

### BACKGROUND

Tubular magnetrons, in which a spatially fixed magnet bar is located, are generally known, the magnetrons being rotatably mounted in a magnetron end block on one side or additionally in a counterbearing, and the magnetron end block providing a rotary drive for the tubular magnetron and, on the other hand, the necessary cooling water and the energy supply for the magnetron.

DE 10 2008 048 785 A1 discloses such a magnetron arrangement having a rotatable tubular magnetron. The end block contains, on the one hand, a rotary drive for the tubular target and, on the other hand, the necessary energy supply for igniting and maintaining a plasma between the tubular magnetron and the substrate to be coated. The tubular target consists of a carrier tube and an externally applied target material.

With such a magnetron arrangement, large-area substrates which are moved past the magnetron can be coated in a vacuum chamber. A particular disadvantage is the fact that only one material can be sputtered during each pass and that, for sputtering other materials, after air has been admitted to the vacuum chamber, a different tubular target must be mounted and the vacuum chamber must be evacuated again.

A further tubular magnetron with an internal magnet system is also disclosed in WO 2003/081 634 A2. The tubular magnetron consists principally of a target carrier in the form of a tube and an outer target, consisting of a multiplicity of planar target plates which rest tangentially on the tubular target carrier, resulting in a gap-free polygonal target surface.

In order to achieve an improvement in this respect, that is to say in order to be able to sputter different materials in succession, commercially available “target turrets” have become available in which a plurality of complete magnetrons offset at an angle are installed about a central axis, which magnetrons require a relatively large installation space as a result of the generation of the necessary magnetic field, of the anodes, of the necessary cooling, and of the current connections, and are quite expensive as a result of their complex construction.

In order to be able to carry out a sputtering operation, the “target turret” must be rotated in fixed angular steps as a function of the number of magnetrons installed until the desired magnetron is located opposite the substrate to be coated, thus enabling a sputter plasma to be ignited between the magnetron and the substrate. The advantage of such a “target turret” can be regarded as the fact that different materials can be sputtered in the same device.

### SUMMARY

It is an object of the present disclosure to provide a multiple sputtering target with which substrates transported along or on a circular path through a vacuum chamber can be coated successively with a selectable multiplicity of materials by magnetron sputtering with little effort.

This is achieved with a multiple sputtering target for magnetron arrangements having tubular magnetrons. The tubular magnetron is mounted in an end block or some other drive unit. A magnet bar is located in the tubular magnetron. At least one polygonal carrier tube having an angular cross section is provided. The polygonal carrier tube has a plurality of longitudinally extending outer surfaces for receiving targets. A free space is located in the at least one polygonal carrier tube. The free space extends longitudinally through the polygonal carrier tube. In the polygonal carrier tube a magnet bar for forming plasma clouds outside the polygonal carrier tube is located in a working position in front of a target which can be selected by rotating the polygonal carrier tube. The moving or stationary substrate is located at a predetermined distance in front of the plasma clouds.

A target of identical or preferably different materials is located on each of the outer surfaces of the carrier tube. The latter allows successive sputtering of different materials onto the same substrate, or onto the same substrates of a batch, without interruption of the vacuum.

The targets are preferably mechanically fastened on the outer surfaces by bonding or in some other way.

In a further embodiment, the polygonal carrier tube has a triangular, quadrangular, pentagonal, hexagonal, heptagonal or octagonal cross section, thus enabling a corresponding number of targets to be accommodated on the polygonal carrier tube.

Finally, the polygonal carrier tube can be rotated in angular steps in such a way that the targets can be positioned individually between the magnet bar and the plasma clouds located in front of the latter.

In a further embodiment, the magnet bar is positioned in a fixed position at the top of the free space, above the axis of symmetry of the latter.

Alternatively, it is also possible for the magnet bar to be positioned in a fixed position at the bottom of the free space, below the axis of symmetry of the latter, or in a fixed position at the side of the free space, to the side of the axis of symmetry of the latter. In this way, the known sputtering methods, sputter-up, sputter-down and sputter-side methods, or else obliquely to the horizontal or vertical, can be implemented in a particularly simple manner by appropriate pivoting or arrangement of the magnet bar.

In a particular variant, two magnet bars located opposite one another are arranged in a fixed position in the free space, in such a way that in each case two plasma clouds are formed at the top and bottom in front of the respective target. In this way, the sputter-up and sputter-down methods can be applied simultaneously to identical or different substrates.

In order to allow better utilization of the targets, the polygonal carrier tube can be moved in an oscillating motion around the fixed magnet bar.

In a further development, the magnet bar located in the free space can be pivoted in angular steps relative to the polygonal carrier tube, with the result that the positions of the magnet bar which are required for the various sputtering methods can be set particularly easily.

Finally, the polygonal carrier tube is connected via a connection element to a commercially available magnetron end block for driving the carrier tube in rotation, for supplying energy and for supplying cooling water to the magnet bar.

The multiple sputtering target can be used equally for carrying out the sputter-up, sputter-side or sputter-down method or can be mounted obliquely to the horizontal or vertical for coating substrates.

In one particular embodiment, two polygonal carrier tubes, each having a magnet bar located in their free space and targets located on their outer surfaces with the same distance or different distances between the magnet bar and the associated target, are arranged in a bipolar arrangement parallel to one another in a common vacuum chamber having a common MF power supply. By simply positioning targets made of different materials, i.e. by rotating both polygonal carrier tubes in angular steps until the desired targets are positioned over the respective magnet bar, virtually any desired material combinations can be produced.

In a further development, a polygonal carrier tube having a magnet bar located in a free space in the latter and a conventional tubular magnetron or a planar magnetron are arranged in a bipolar arrangement parallel to one another in a common vacuum chamber having a common MF power supply. Here too, it is possible to produce a multiplicity of material combinations on a substrate, and it is also possible to include materials which are actually only available for planar magnetrons.

With the polygonal carrier tube of the multiple sputtering target which can be rotated in angular steps, it is possible to sputter a plurality of different or identical materials in succession and to deposit them on a substrate with substantially less effort.

For multiple sputtering, polygonal elongate carrier tubes having an angular cross section are used for this purpose instead of the customary elongate tubular targets, in which polygonal elongate carrier tubes targets made of different or identical materials are applied as sputtering sources to the longitudinally extending outer surfaces.

The targets can be fastened to the preferably equally large outer surfaces of the carrier tubes, which during sputtering serve as material sources for the coatings to be applied to a substrate, by means of conventional clamping rails (claws) or by bonding.

The carrier tubes can have a multiplicity of cross sections, such as a triangle, a quadrilateral, a pentagon, a hexagon, a heptagon or else an octagon, and can be covered with a corresponding number of targets made of different materials. Special shapes, such as a carrier tube with a triangular or quadrangular cross section and three or four different targets as well as with beveled corners, are also possible.

The novel multiple sputtering target provides the following advantages:
The use of different or identical target materials in a coating process is made possible without having to admit air to the vacuum chamber in between because of target changes or magnetron changes.
Multiple coatings with the same target materials are also possible, this being particularly advantageous for increasing the service life of the installation.
It is possible to use two, three and up to eight targets 2 of different materials on the polygonal carrier tube 1.
An extremely small space requirement is achieved.
The target materials can be “changed” in angular steps by simply rotating the polygonal carrier tube 1 further.
A standard magnetic field of a tubular magnetron with a standard magnet bar can be used.
Only a single cooling system is required, as in the case of a tubular magnetron.
A standard tubular target end block can be used as a receptacle and drive for the polygonal carrier tube.
Only a single energy supply is required.
The target can be used together with already existing standard end blocks and standard magnet bars of typical tubular cathode sputter sources.
The use of bipolar arrangements results in a wide variety of material mixing possibilities.
It is possible to achieve long machine service lives if, for example, identical targets are mounted and the sputtered-through target is always rotated further.
It allows high flexibility for coatings with different materials.
The investment costs for the customer are comparatively low because the multiple targets can also be used in existing tubular magnetron systems.
It is possible without problems to use the multiple sputtering targets together with customary tubular or planar targets in an arrangement parallel next to one another and having a common MF power supply, leading to greater flexibility of the installation.

The following detailed description is merely exemplary in nature and is not intended to limit the invention or the application and uses of the invention. Furthermore, there is no intention to be bound by any theory presented in the preceding background or the following detailed description.

### BRIEF DESCRIPTION OF THE DRAWINGS

FIG. 1: shows a multiple sputtering target consisting of a polygonal carrier tube in cross section with a three-fold target system rotatable in angular steps on the outer surfaces and with a magnet bar within the carrier tube with three targets and indicated plasma clouds in front of the target, in each case located at the top, as well as a substrate guided past above the plasma clouds;

FIG. 2a: shows a multiple sputtering target with a polygonal carrier tube as in FIG. 1, but as a four-fold target system with four targets;

FIG. 2b: shows a multiple sputtering target with a polygonal carrier tube as in FIG. 1 with four-fold target system, but with beveled edges;

FIG. 3: shows a multiple sputtering target with a polygonal carrier tube as in FIG. 1 with a five-fold target system;

FIG. 4: shows a multiple sputtering target with a polygonal carrier tube as in FIG. 1 with a six-fold target system;

FIG. 5: shows a multiple sputtering target with a polygonal carrier tube as in FIG. 1 with an eight-fold target system;

FIG. 6: shows a schematic side view of a polygonal carrier tube of a multiple sputtering target mounted on an end block;

FIG. 7: shows a multiple sputtering target with a polygonal carrier tube in which a magnet bar is positioned in the lower region of the free space;

FIG. 8: shows a multiple sputtering target with a polygonal carrier tube in which a magnet bar is positioned at the side of the free space;

FIG. 9: shows a multiple sputtering target with a polygonal carrier tube in which two magnet bars are positioned in the free space at the top and bottom respectively according to the drawing, with the result that two plasma clouds are formed in each case at the top and bottom in front of the corresponding targets, past each of which a substrate can be guided;

FIG. 10: shows a parallel arrangement of two multiple sputtering targets with a common MF power supply for depositing identical materials on a substrate;

FIG. 11: shows a parallel arrangement of two multiple sputtering targets with a common MF power supply for depositing different materials on a substrate;

FIG. 12: shows a parallel arrangement of a multiple sputtering target and a tubular magnetron having a common MF power supply for depositing various materials on a substrate; and

FIG. 13: shows a parallel arrangement of two four-fold sputtering targets in a symmetrical and asymmetrical embodiment with a different distance between the magnet bar and the target.

### DETAILED DESCRIPTION

The multiple sputtering target in the form of a polygonal carrier tube 1 is equipped with a plurality of outer surfaces 3 for receiving targets 2, wherein a magnet bar 4 is located in a free space 5 within the polygonal carrier tube 1. The free space 5 extends longitudinally through the center of the carrier tube 1 and preferably has an annular cross section.

It is self-evident that the coatings described below with the various variants of the multiple sputtering target with the polygonal carrier tube 1 must be produced under a vacuum in a vacuum chamber (not illustrated).

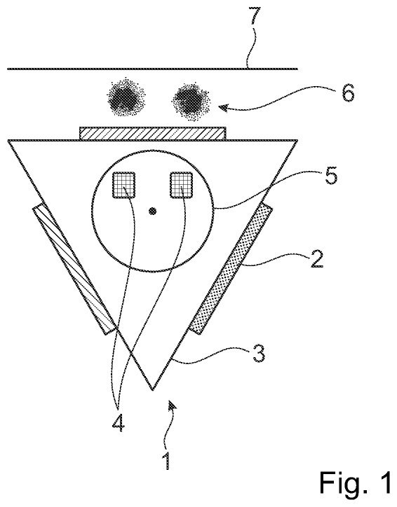

FIG. 1 shows a polygonal carrier tube 1 of a multiple sputtering target with a three-fold target system which can be rotated in angular steps and has three targets 2, which are fastened individually in each case to an outer surface 3 of the carrier tube 1 with a triangular cross section, wherein the targets 2 can consist of the same or preferably of different materials.

The spatially fixed magnet bar 4, which is positioned at the top in the free space 5, that is to say above the axis of symmetry of the latter, is located within the carrier tube 1. With the magnet bar 4, two plasma clouds 6 are generated in front of the respective target 2 located at the top on the carrier tube 1, with the aid of which a substrate 7 located above or guided past the plasma clouds 6 is coated with the material sputtered off from the target 2 in the sputter-up method.

As is known, the sputter-up method has the advantage that sputtered particles which are accelerated primarily upward are deposited on the substrate 7.

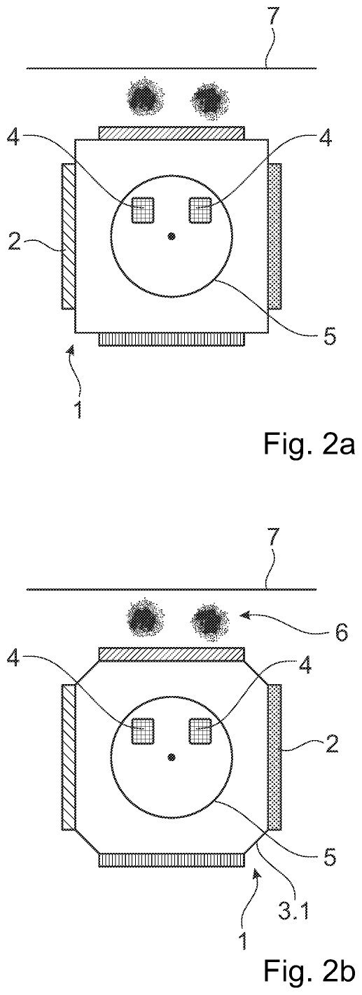

FIG. 2a shows a polygonal carrier tube 1 with a square cross section having four longitudinally extending outer surfaces 3, on each of which a target 2 is fastened. In the free space 5, the magnet bar 4 is located above the axis of symmetry of the latter.

FIG. 2b shows a multiple sputtering target with a polygonal carrier tube 1 with a similar structure to that in FIGS. 1 and 2a but with four longitudinally extending outer surfaces 3 with beveled edges 3.1 of the polygonal carrier tube 1.

In principle, such beveled edges can also be implemented in a three-fold target system according to FIG. 1.

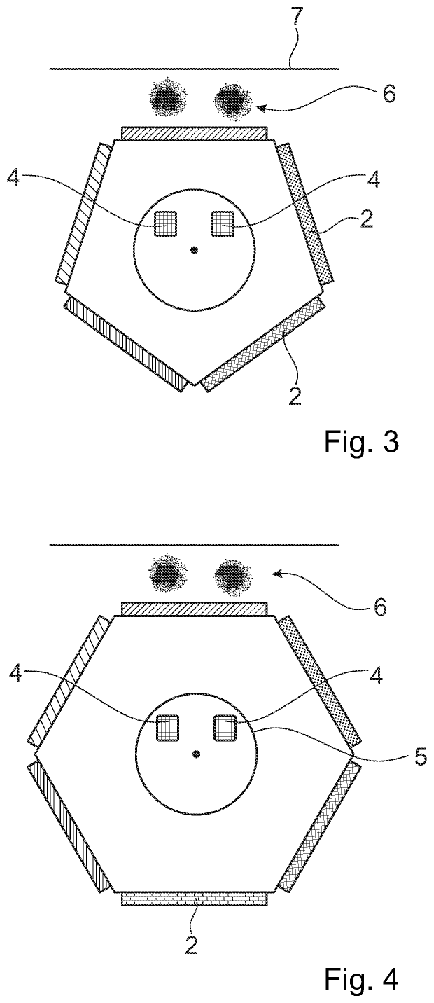

FIG. 3 shows a multiple sputtering target with a polygonal carrier tube 1 with a structure as in FIG. 1 but as a five-fold target system with five longitudinally extending outer surfaces 3 of the carrier tube 1 for receiving a maximum of five targets 2.

Furthermore, FIG. 4 shows a multiple sputtering target with a polygonal carrier tube 1 with a structure as in FIG. 1 but with a six-fold target system with six longitudinally extending outer surfaces 3 for receiving a total of six targets 2.

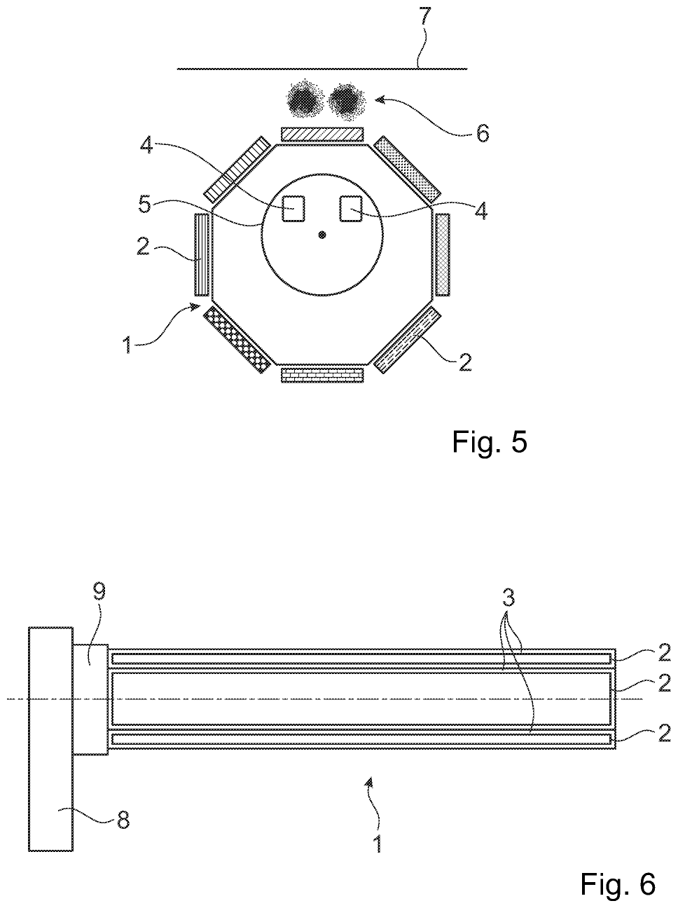

FIG. 5 shows a multiple sputtering target with a polygonal carrier tube 1 with a structure as in FIG. 1 but with an eight-fold target system with eight longitudinally extending outer surfaces 3 for receiving one target 2 each.

In most of the variants described above, the magnet bar 4 is located in the free space 5, above the axis of symmetry of the latter, the free space 5 extending centrally through the carrier tube 1.

An exception to this positioning can be useful, if the polygonal carrier tube 1 has a particularly large diameter, to prevent the distance between the magnet bar 4 in the polygonal carrier tube 1 and the target 2 on the outer surface 3 of the carrier tube 1 from becoming too large and the intensity of the plasma clouds 7 from being weakened as a result. In this case, said distance should be reduced.

The different hatching of the targets 2 fastened on the outer surfaces 3 of the carrier tube 1 is intended to symbolize different materials in each case. In order to select the material to be sputtered off, the carrier tube 1 has only to be rotated in equal angular steps until the desired target 2 is positioned at the top above the magnet bar 4. The required plasma clouds 6 are then generated during operation of the magnet bar 4 in front of the target 2 located at the top.

The polygonal carrier tubes 1 with different cross sections can be operated with a commercially available magnetron end block 8 via a connection element 9, it being possible for a spatially fixed magnet bar 4 of a conventional tubular target to be used in the interior of the carrier tube 1. FIG. 6 shows a side view of a hexagonal carrier tube 1 with the targets 2 located on the outer surfaces 3.

Particularly long carrier tubes 1 can be mounted with their free end in a counterbearing (not illustrated) in order to limit deflections to a minimum.

The sputter plasma required for sputtering is generated by the magnet bar 4 in the vicinity of the target surface due to the magnetic field. By rotating the carrier tube 1 with the targets 2 located thereon, different or identical materials can thus be sputtered off in succession with respect to the magnet bar 3—depending on how the targets 2 are distributed on outer surfaces 3 of the carrier tube 1—and a substrate 7 guided past can be coated accordingly. In addition, an oscillating motion of the polygonal carrier tube 1 or of the magnet bar 4 can achieve an expanded target erosion field, whereby better use of the targets 2 is achieved.

FIG. 1 to FIG. 5 of the drawing show the sputtering device for operation in the sputter-up method. This means that the particles sputtered off from the target 2 move upward in the direction of the substrate 7 to be coated, which is moved past above the plasma clouds 6.

Other sputtering methods, such as the sputter-down method, can be implemented in a simple manner with the multiple sputtering target in conjunction with the polygonal carrier tube 1 described above, in that the magnet bar 4 is pivoted downward by 180 axis about an imaginary pivoting axis, with the result that the magnet bar 4 is below the axis of symmetry of the free space 5. Alternatively, the magnet bar 4 is to be positioned pointing downward in the free space 5, with the result that the plasma clouds 6 are formed in front of a target 2 located at the bottom on the carrier tube 1.

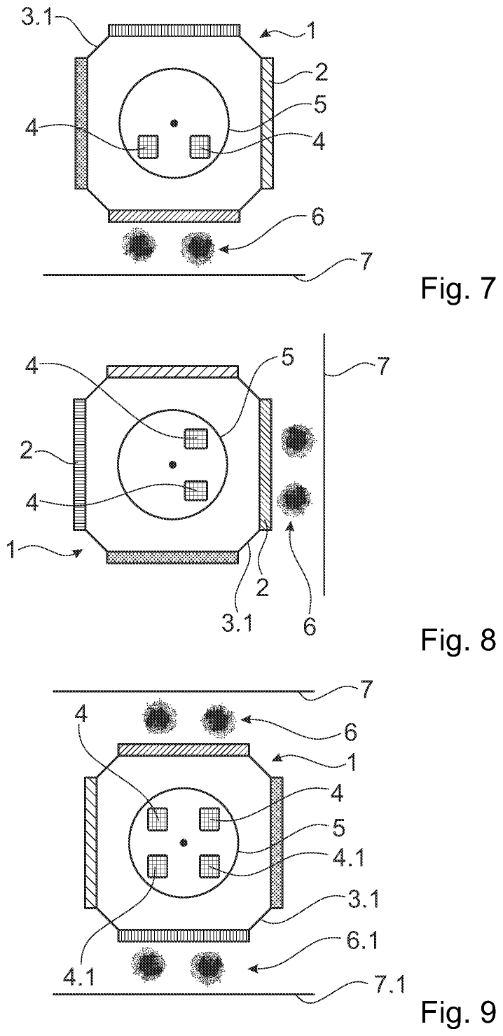

In this case, the particles sputtered off from the target 2 are deposited on a substrate 7 to be coated, which is guided past below the plasma clouds 6. (FIG. 7)

If a sputter-side method, i.e. lateral deposition on a substrate 7, is to be implemented, then the magnet bar 4 would have to be moved through 90° into a lateral position, with the result that the plasma clouds 6 are formed in front of the target 2 to be positioned laterally. In this case, the substrate 7 to be coated would have to be positioned or passed laterally perpendicularly in front of the plasma clouds 6. (FIG. 8)

A special embodiment is illustrated in FIG. 9. The polygonal carrier tube 1 described is equipped here with a central free space 5 in which two magnet bars 4, 4.1 are arranged respectively above and below the axis of symmetry. In this way, two plasma clouds 6, 6.1 can be formed at the top and bottom in front of the corresponding targets 2, past which clouds a respective substrate 7, 7.1 can be guided or at which it can be positioned. The prerequisite for this embodiment is that the polygonal carrier tube 1 has an even number of outer surfaces 3.

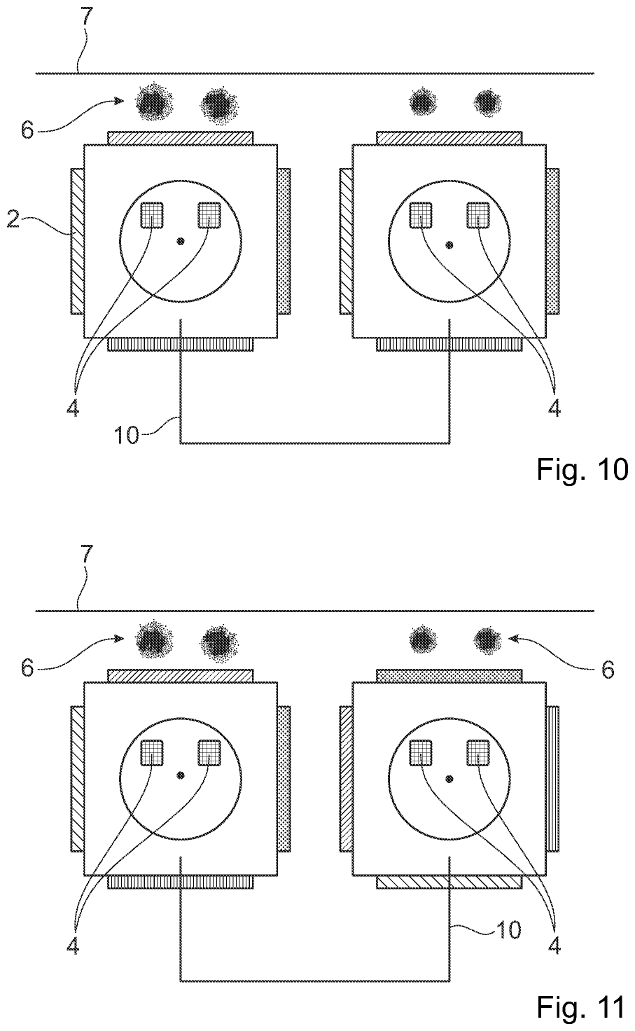

FIGS. 10 to 11 show special embodiments with multiple sputtering targets or in combination with a conventional tubular magnetron in order to be able to carry out a bipolar process in a common vacuum chamber. The flexibility of a sputtering installation is thereby considerably increased.

A parallel arrangement of two multiple sputtering targets with a common MF power supply 10 for depositing identical materials on a substrate 7 is illustrated in FIG. 10.

FIG. 11 shows basically the same parallel arrangement of two multiple sputtering targets with a common MF power supply for depositing different materials on a substrate, wherein here the polygonal carrier tube 1 on the right according to the drawing is rotated upward with another target 2 into the coating position. This allows the deposition of various material combinations on a substrate 7.

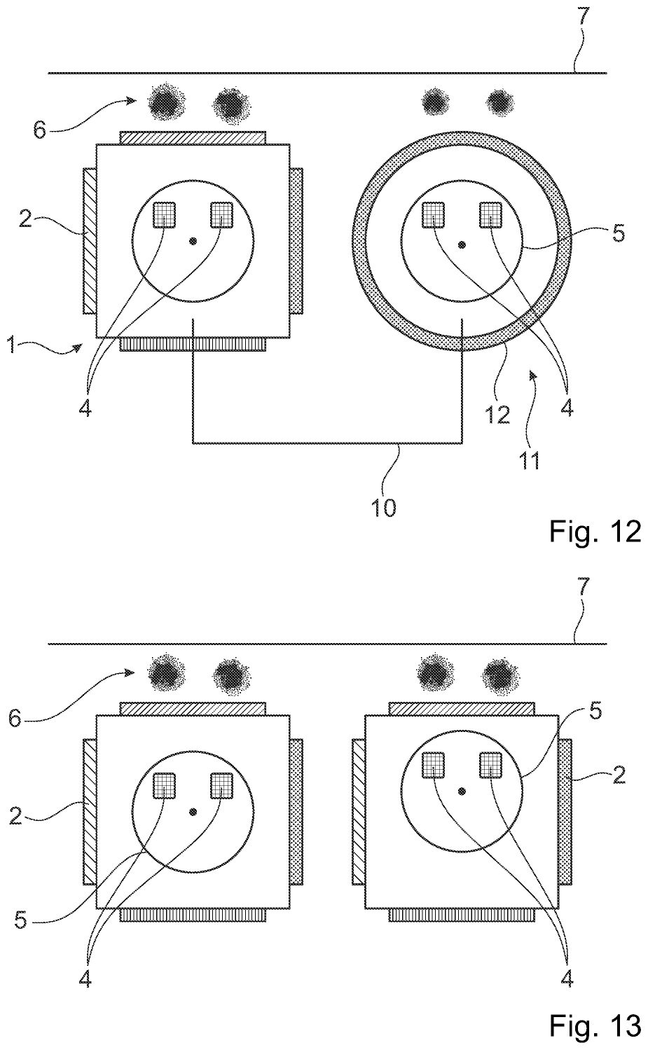

FIG. 12 shows a special variant with a simultaneously operated parallel arrangement of a multiple sputtering target and a conventional tubular magnetron 11 having a common MF power supply 10 for depositing various materials on a substrate 7. The tubular magnetron 11 contains a central free space 5, in which a magnet bar 4 is located and which is surrounded by a tubular target 12.

Finally, FIG. 13 shows a parallel arrangement of two multiple sputtering targets with a common MF power supply for depositing identical materials on a substrate 7, each having a polygonal carrier tube 1 and a magnet bar 4 located in the free space 5, wherein the multiple sputtering target on the left according to the drawing is of symmetrical design and the multiple sputtering target on the right according to the drawing is of asymmetrical design. It is thereby possible to achieve different distances between the magnet bar 4 and the target 2. It is thereby possible to carry out sputtering out with magnetic fields of different strengths.

A combination of a multiple sputtering target with a conventional planar magnetron (not illustrated) and with a common MF power supply in a common vacuum chamber is also possible without problems. With this combination too, it is possible to deposit material combinations on the substrate which is to be guided past.

Instead of the polygonal carrier tubes illustrated in FIGS. 7-9 with four outer surfaces 3 and beveled edges 3.1, the polygonal carrier tubes 1 can also have the cross-sectional shapes illustrated in the other figures of the drawing.

The advantage of this embodiment of the multiple sputtering target allows sputter-up and sputter-down methods to be carried out simultaneously.

Standard magnet bars or any other suitable magnet bars can be used as magnet bars 4 in the free space 5.

The round connection elements 9 required for operation on a magnetron end block 8 and in the support bearing can be joined to the carrier tube 1 by welding, or a corresponding connection element 9 is used as an adapter. (FIG. 6)

Instead of the commercially available magnetron end block 7, it is also possible to use other suitable receiving devices with adjusting motors, provided that an angularly accurate rotary movement is produced in order to bring the various targets 2 on the polygonal carrier tube 1 into the correct position, i.e. parallel to the substrate 7, 7.1 to be coated.

An oscillating motion of the polygonal carrier tube 1 of the multiple target about the fixed magnet bar is also conceivable.

While the present invention has been described with reference to exemplary embodiments, it will be readily apparent to those skilled in the art that the invention is not limited to the disclosed or illustrated embodiments but, on the contrary, is intended to cover numerous other modifications, substitutions, variations and broad equivalent arrangements that are included within the spirit and scope of the following claims.

### LIST OF REFERENCE SIGNS

1 carrier tube
2 target
3 outer surface
3.1 beveled edge
4 magnet bar
4.1 magnet bar
5 free space
6 plasma cloud
6.1 plasma cloud
7 substrate
7.1 substrate
8 magnetron end block
9 connection element
10 MF power supply
11 tubular magnetron
12 tubular target

What is claimed is:

1. A sputtering target for sputter-coating a substrate in a vacuum chamber, comprising:
a polygonal carrier tube (1) having an angular cross section with a plurality of longitudinally extending outer surfaces (3) for receiving targets (2);
a free space (5) located in the polygonal carrier tube (1) and extending longitudinally through the polygonal carrier tube (1); and
a magnet bar (4) arranged in the free space (5) for forming plasma clouds (6) outside the polygonal carrier tube (1) in front of a selected one of the targets (2),
wherein the selected one of the targets (2) can be selected by rotating the polygonal carrier tube, and
wherein the substrate (7) is located at a predetermined distance in front of the plasma clouds (6).

2. The sputtering target as claimed in claim 1,
wherein one of the targets (2) is located on each of the outer surfaces (3) of the polygonal carrier tube (1), and
wherein the targets (2) are made of the same material.

3. The sputtering target as claimed in claim 1,
wherein one of the targets (2) is located on each of the outer surfaces (3) of the polygonal carrier tube (1), and
wherein the targets (2) are made of different materials.

4. The sputtering target as claimed in claim 1,
wherein the polygonal carrier tube (1) has a triangular, quadrangular, pentagonal, hexagonal, heptagonal or octagonal cross section.

5. The sputtering target as claimed in claim 1,
wherein the polygonal carrier tube (1) can be rotated in angular steps in such a way that the targets (2) can be positioned individually between the magnet bar (4) and the plasma clouds (6).

6. The sputtering target as claimed in claim 1,
wherein the magnet bar (4) is positioned in a fixed position at a top of the free space (5), above an axis of symmetry of the latter.

7. The sputtering target as claimed in claim 1,
wherein the magnet bar (4) is positioned in a fixed position at a bottom of the free space (4), below an axis of symmetry of the latter.

8. The sputtering target as claimed in claim 1,
wherein the magnet bar (4) is positioned in a fixed position at a side of the free space (5), to a side of an axis of symmetry of the latter.

9. The sputtering target as claimed in claim 1,
wherein a further magnet bar (4,1) is arranged opposite the magnet bar (4) in a fixed position in the free space (5), in such a way that there are respective plasma clouds (6, 6.1) at a top and a bottom in front of the respective target (2).

10. The sputtering target as claimed in claim 1,
wherein the polygonal carrier tube (1) can be moved in an oscillating motion around the magnet bar (4).

11. The sputtering target as claimed in claim 1,
wherein the magnet bar (4) can be pivoted in the free space (5) about a virtual axis in relation to the polygonal carrier tube (1) in any desired angular steps.

12. The sputtering target as claimed in claim 1,
wherein the polygonal carrier tube (1) is connected via a connection element (9) to a magnetron end block (8) for driving the polygonal carrier tube (1) in rotation and for supplying energy and for supplying cooling water to the magnet bar (4).

13. A system, comprising:
a first and a second sputtering target as claimed in claim 1,
the first and the second sputtering target being in a bipolar arrangement parallel to one another in a common vacuum chamber and operatively connected to a common MF power supply (10).

14. A system, comprising:
the sputtering target as claimed in claim 1; and
a tubular or planar magnetron (11),
the sputtering target and the tubular or planar magnetron being in a bipolar arrangement parallel to one another in a common vacuum chamber and operatively connected a common MF power supply (10).
